(19) United States
(12) Patent Application Publication
(10) Pub. No.: US 2015/0163870 A1
(43) Pub. Date: Jun. 11, 2015

(54) PWM CIRCUIT AND LED DRIVE CIRCUIT

(71) Applicant: SUPEC (SUZHOU) CO., LTD., Jiangsu (CN)

(72) Inventor: Lixin Fan, Jiangsu (CN)

(21) Appl. No.: 14/000,508

(22) PCT Filed: Aug. 14, 2012
(86) PCT No.: PCT/CN12/80075

§ 371 Date: Aug. 20, 2013

(30) Foreign Application Priority Data
Apr. 6, 2012 (CN) 201210099325.0

(51) Int. Cl. H05B 33/08; H03K 3/017; H05B 37/02

(52) U.S. Cl. CPC H05B 33/0809; H05B 37/0281; H03K 3/017

(57) ABSTRACT

A PWM circuit is disclosed in the application, which includes: a PWM counter, a reference value setting register, a frequency multiplier and a comparator, where the frequency multiplier is adapted to increase the frequency of a clock signal input and to output the clock signal with the increased frequency to the PWM counter. An LED drive circuit is further disclosed in the application. The frequency of a PWM input clock signal is increased to N times of the original frequency of the PWM input clock signal by the frequency multiplier, so that the counting cycle of the PWM counter is shortened to 1/N of the original counting cycle of the PWM counter. Therefore, in the dynamic LED display screen, the refresh frequency can be increased to N times of the original refresh frequency while the original resolution is maintained.

This application claims the priority to Chinese patent application No. 201210099325.0, titled “PWM CIRCUIT AND LED DRIVE CIRCUIT” and filed with the State Intellectual Property Office on Apr. 6, 2012, which is hereby incorporated by reference in its entirety.

### FIELD OF THE INVENTION

The application relates to the field of Light Emitting Diode (LED) display screens, and particularly to a Pulse Width Modulation (PWM) circuit and an LED drive circuit.

### BACKGROUND OF THE INVENTION

PWM is an effective technique to control an analog circuit using digital outputs of a microprocessor, and it is widely used in many fields, such as fields of measurement, communication, power control and conversion.

Referring to FIG. 1, in the prior art, a PWM circuit 10 generally includes: a PWM counter 11 adapted to perform up/down counting for a clock signal; a reference value setting register 12 adapted to set a comparison reference value which determines the duty cycle of a PWM signal; and a comparator 13 adapted to compare the count value of the PWM counter with the comparison reference value set by the reference value setting register and generate an effective PWM signal.

In LED display screen, the PWM technique is adopted in order to improve the display resolution. Usually the PWM is 16 bit. In the conventional LED display screen, a serial bus including SDI (Serial Digital Input), DCLK (Serial Data Input Clock), LE (Latch Enable), GCLK (Graph Clock Input) and SDO (Serial Data Output) is usually adopted, in which the GCLK is an input clock of the PWM and the frequency of the GCLK is less than 30 MHz. There are two types of the LED display screen: dynamic display screen and static display screen. For the static display screen, each LED pixel is driven by a separate constant current source; whereas for the dynamic display, time-sharing driving is adopted, in which LEDs of each column share the same constant current source for driving. The display brightness of the LED is determined by the duty cycle output by the PWM.

In a dynamic scanning system, a display refresh frequency greater than 2 KHz is required. And generally, the PWM has a resolution of 16 bit. Due to effect of the frequency of the GCLK, the number of GCLKs for forming a pulse cycle of a 16 bit PWM is: 2¹⁶=65536. If the frequency of GCLK is 30 MHz, then the length of one cycle of the 16 bit PWM is: 65536/30M=2.19 ms; and the refresh frequency is 458 Hz. If the dynamic scanning is “4-scan”, then the refresh frequency of the LED display screen is 458/4=114.5 Hz. In order to meet practical requirements of application and increase the dynamic refresh frequency, it can only reduce the cycle length of the PWM, i.e., reduce the bit length of PWM. For example, if the bit length of the PWM is 12 bit, the refresh frequency may be 1824 Hz. However, the reduction of the bit length may cause a decrease in resolution, therefore the contradiction between the refresh frequency and the resolution of the dynamic display screen can not be solved in the conventional solution.

### SUMMARY OF THE INVENTION

In view of this, a PWM circuit and an LED drive circuit applied to an LED display screen are provided according to the application. By the PWM circuit and the LED drive circuit, the refresh frequency can be improved while the original resolution is maintained.

In order to achieve the above object, a technical solution according to the application is as follows.

A PWM circuit, which includes:

a PWM counter, adapted to count a clock signal;

a reference value setting register, adapted to set a comparison reference value which determines the duty cycle of a PWM signal;

a frequency multiplier, adapted to increase the frequency of an clock signal input and to output the clock signal with the increased frequency to the PWM counter; and

a comparator, adapted to generate a PWM signal based on a comparison between the comparison reference value and the count value of the PWM counter.

Preferably, in the above PWM counter, the frequency multiplier is one of a transistor frequency multiplier, a varactor diode frequency multiplier, a step recovery diode frequency multiplier, a ferrite frequency multiplier, a phase-locked loop frequency multiplier and a synchronous frequency multiplier.

Preferably, in the above PWM counter, the PWM circuit further includes a count value upper-limit setting register, for setting a count value upper-limit which determines the pulse width of the PWM signal in the PWM counter.

Preferably, the comparator is adapted to output an “L” level as the PWM signal when the count value of the PWM counter is lower than the comparison reference value, and to output an “H” level as the PWM signal when the count value of the PWM counter is higher than the comparison reference value.

Preferably, the comparator is adapted to output an “H” level as the PWM signal when the count value of the PWM counter is lower than the comparison reference value, and to output an “L” level as the PWM signal when the count value of the PWM counter is higher than the comparison reference value.

An LED drive circuit is also provided according to the application, and the LED drive circuit includes:

the PWM circuit described above;

an LED light source; and

a drive module connected between the PWM circuit and the LED light source, for supplying stable current to the LED light source.

Preferably, in the above LED drive circuit, the frequency multiplier is one of a transistor frequency multiplier, a varactor diode frequency multiplier, a step recovery diode frequency multiplier, a ferrite frequency multiplier, a phase-locked loop frequency multiplier and a synchronous frequency multiplier.

Preferably, in the LED drive circuit described above, the PWM circuit further includes a count value upper-limit setting register, for setting a count value upper-limit which determines the pulse width of the PWM signal in the PWM counter.

Preferably, the comparator is adapted to output an “L” level as the PWM signal when the count value of the PWM counter is lower than the comparison reference value, and to output an “H” level as the PWM signal when the count value of the PWM counter is higher than the comparison reference value.

Preferably, the comparator is adapted to output an “H” level as the PWM signal when the count value of the PWM counter is lower than the comparison reference value, and to output an “L” level as the PWM signal when the count value of the PWM counter is higher than the comparison reference value.

As can be seen from the above technical solutions, the PWM circuit provided by the application includes: a PWM counter, a reference value setting register, a frequency multiplier and a comparator, where the frequency multiplier is used to increase the frequency of a clock signal and output the clock signal with the increased frequency to the PWM counter. The frequency of the PWM input clock signal is increased to N times of the original frequency of the PWM input clock signal by the frequency multiplier, so that the counting cycle of the PWM counter is shortened to 1/N of the original counting cycle of the PWM counter. Therefore, in the dynamic LED display screen, the refresh frequency can be increased to N times of the original refresh frequency while the original resolution is maintained.

### BRIEF DESCRIPTION OF THE DRAWINGS

To more clearly illustrate embodiments of the application or technical solutions in the prior art, drawings to be used in the description of the embodiments of the application or the prior art will be briefly introduced hereinafter. Apparently, the drawings described below are only some embodiments recorded in the application, and those skilled in the art can also obtain other drawings from these drawings without any creative efforts.

FIG. 1 is a block diagram illustrating the basic structure of a PWM circuit in the prior art;

FIG. 2 is a block diagram illustrating the basic structure a PWM circuit in a specific embodiment according to the application;

FIG. 3 is an operation time sequence diagram of the PWM circuit shown in FIG. 2; and

FIG. 4 shows an LED drive circuit in a specific embodiment according to the application.

### DETAILED DESCRIPTION OF THE INVENTION

To make those skilled in the art to better understand the technical solution of the application, the technical solution in the embodiments of the application will be illustrated clearly and completely hereinafter in conjunction with the drawings. Apparently, the described embodiments are only some embodiments of the application, rather than all embodiments. All other embodiments obtained by those skilled in the art without any creative efforts should fall within the scope of protection of the application.

A PWM circuit is provided according to an embodiment of the application. The PWM circuit includes:

a PWM counter, adapted to count a clock signal;

a reference value setting register, adapted to set a comparison reference value which determines the duty cycle of a PWM signal;

a frequency multiplier, adapted to increase the frequency of an clock signal and output the clock signal with the increased frequency to the PWM counter; and

a comparator, adapted to generate a PWM signal based on a comparison between the comparison reference value and the count value of the PWM counter;

The frequency multiplier is used to increase the frequency of an input pulse signal to N times of the original frequency of the input pulse signal, where N may be an integer greater than 1 or a decimal greater than 1. The frequency multiplier may be a transistor frequency multiplier, a varactor diode frequency multiplier, a step recovery diode frequency multiplier, etc.; the frequency multiplier may also be a frequency multiplier constituted by non-linear resistors, inductors and capacitors, such as a ferrite frequency multiplier; in a device requiring small frequency multiplication noise, the frequency multiplier may also be a phase-locked loop frequency multiplier and a synchronous frequency multiplier formed according to the principle of a phase-locked loop. In the technical solution according to the application, the frequency multiplier is preferably a phase-locked loop. In other embodiments, the frequency multiplication of the input counting frequency of the PWM counter may be achieved by the DCLK on a serial bus.

The phase-locked loop is constituted by a phase detector, a loop filter and a voltage controlled oscillator. The phase detector is used to detect a phase difference between an input signal and an output signal and output an error voltage. The noise and interference components in the error voltage are filtered by the loop filter which is a low-pass one, so as to form a control voltage for the voltage controlled oscillator. The result of applying the control voltage to the voltage controlled oscillator is to pull the output oscillation frequency of the voltage controlled oscillator to the input signal frequency of the loop, and when the output oscillation frequency and the input signal frequency are equal, the loop is locked, which is referred to as in-lock. The DC control voltage for maintaining the locking is provided by the phase detector, therefore, a certain phase difference is retained between the two input signals of the phase detector.

The comparator is a circuit for comparing an analog voltage signal and a reference voltage. The two inputs of the comparator are both analog signals, while the output of the comparator is a binary signal. When the difference between the input voltages increases or decreases, the output of the comparator remains constant.

The PWM circuit further includes a count value upper-limit setting register, for setting a count value upper-limit which determines the pulse width of the PWM signal in the PWM counter.

An LED drive circuit is also provided according to an embodiment of the application. The LED drive circuit includes:

the PWM circuit described above;

an LED light source; and

a drive module connected between the PWM circuit and the LED light source.

The frequency of the PWM input clock signal is increased to N times of the original frequency of the PWM input clock signal by the frequency multiplier, so that the counting cycle of the PWM counter is shortened to 1/N of the original counting cycle of the PWM counter. Therefore, in the dynamic LED display screen, the refresh frequency can be increased to N times of the original refresh frequency while the original resolution is maintained.

In the LED drive circuit, the frequency multiplier is preferably a phase-locked loop. The PWM circuit further includes a count value upper-limit setting register, for setting a count value upper-limit which determines the pulse width of the PWM signal in the PWM counter.

To further illustrate the technical solution of the application, the preferred embodiments of the application will be described hereinafter in conjunction with the drawings. However, it should be understood that, these descriptions are only to further illustrate features and advantages of the application, without forming limitations to the claims of the application.

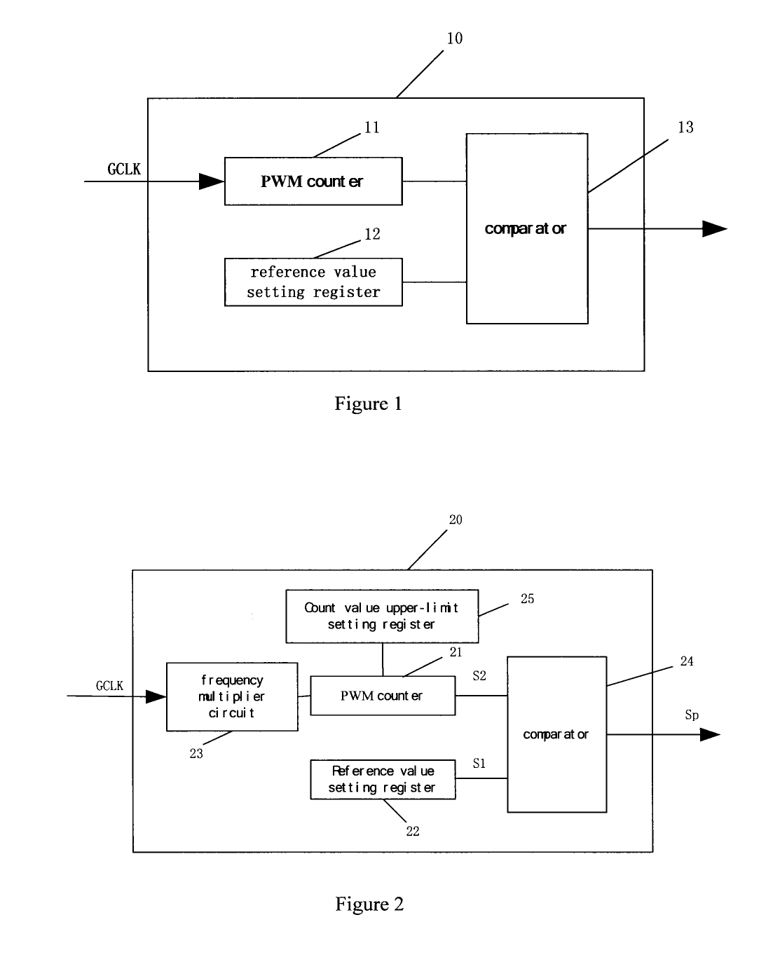

Referring to the block diagram in FIG. 2, the basic structure of a PWM circuit of the application is shown.

The PWM circuit 20 includes: a PWM counter 21, a reference value setting register 22, a frequency multiplier 23, a comparator 24 and a count value upper-limit setting register 25.

The PWM counter 21 is adapted to count a clock signal GCLK.

The reference value setting register 22 is adapted to set a comparison reference value S1 which determines the duty cycle of a PWM signal Sp;

The frequency multiplier 23 is adapted to increase the frequency of the clock signal GCLK and output the clock signal GCLK with the increased frequency to the PWM counter 21;

The comparator 24 is adapted to compare the count value S2 of the PWM counter 21 with the comparison reference value Si in the reference value setting register 22, and generate the PWM signal Sp.

The count value upper-limit setting register 25 is adapted to input a count value upper-limit which determines the pulse width of the PWM signal to the PWM counter 21.

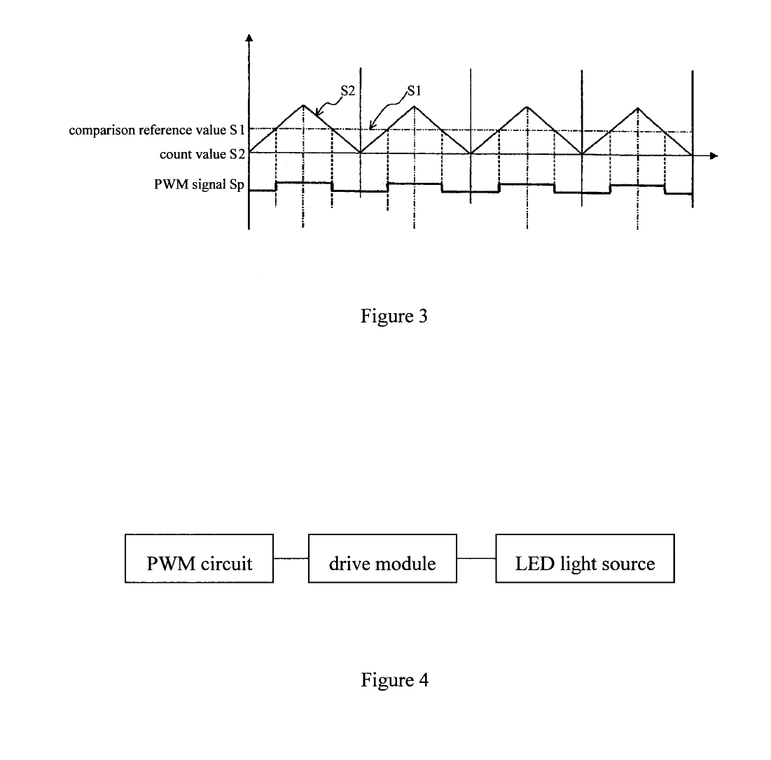

FIG. 3 shows an operation time sequence diagram of the PWM circuit 20.

The frequency multiplier 23 multiplies the frequency f of the input clock signal GCLK, and the frequency of the multiplied clock signal GCLK is Nf, where N is an integer greater than 1. The input clock signal GCLK with the frequency Nf is counted by the PWM counter 21. A count value upper-limit S3 from the count value upper-limit setting register 25 is input to the PWM counter 21. Up/down counting between “0” and the count value upper-limit S3 is performed by the PWM counter 21. The count value S2 of the PWM counter 21 is input to one input terminal of the comparator 24. A comparison reference value S1 in the reference value setting register 22 is input to another input terminal of the comparator 24. The comparator 24 compares the count value S2 with the comparison reference value S1, and when the count value S2 is lower than the comparison reference value S1, an “L” level is output from the comparator 24 as the PWM signal Sp, and when the count value S2 is higher than the comparison reference value S1, an “H” level is output from the comparator 24 as the PWM signal Sp, and when the count value S2 is lower than the comparison reference value S1 again, the “L” level is output from the comparator 24 as the PWM signal Sp.

Of course, in the preferred embodiment of the application, the comparator may also output an “H” level as the PWM signal when the count value of the PWM counter is lower than the comparison reference value, and output an “L” level as the PWM signal when the count value of the PWM counter is higher than the comparison reference value.

Referring to FIG. 4, an LED drive circuit in a specific embodiment of the application is shown.

The LED drive circuit 30 includes a PWM circuit 20, an LED light source 31 and a drive module 32.

The drive module 32 is connected between the PWM circuit and the LED light source, for supplying stable current to the LED light source 31.

In the conventional LED display screen, if a high resolution, such as a 16 bit solution, is adopted, the refresh frequency of the LED display screen is relatively low due to the frequency limitation of the GCLK on the bus, therefore a static display screen is usually adopted, which results in a high cost. However, when the frequency multiplier is adopted, the input frequency for the PWM counting is increased, thus a dynamic display screen solution can be adopted to achieve a refresh frequency higher than 2 KHz while with a resolution of 16 bit. With four (or more) groups of scanning, the number of the used LED drivers can be decreased. For example, with fours groups of scanning, the number of the LED drivers can be decreased to ¼ of the number of the originally used LED drivers, thereby saving a lot of hardware overhead.

In the following, the advantages of the technical solution of the application will be illustrated by examples.

Assuming that in the LED display screen the frequency of GCLK on the bus is Fclk, the refresh frequency is Fs, the resolution is K (Bit), and the PWM counting clock frequency is Fct;

Fct=Fs*2K;

Fs=Fct/(2K);

in a conventional mode, Fct=Fclk, that is, the PWM counting clock is the GCLK on the bus, thus

Fs=Fclk/(2K); (I)

When the frequency multiplier is adopted, assuming that the frequency of the output of the frequency multiplier is N times of the frequency of the input of the frequency multiplier, then Fct=N*Fclk;

thus,

Fs=N*Fclk/(2K); (II)

Comparing equations I and II, it can be viewed as that, in the case of the same frequency of GCLK on the bus and the same resolution, when the frequency multiplier is adopted, the refresh frequency of the LED display screen can be increased to N times of the original refresh frequency.

In summary, the PWM circuit provided by the application includes: a PWM counter, a reference value setting register, a frequency multiplier and a comparator, in which the frequency multiplier is adapted to increase the frequency of the clock signal and output the clock signal with the increased frequency to the PWM counter. The frequency of the PWM input clock signal is increased to N times of the original frequency of the PWM input clock by the frequency multiplier, so that the counting cycle of the PWM counter is shortened to 1/N of the original counting cycle of the PWM counter. Therefore, in the dynamic LED display screen, the refresh frequency can be increased to N times of the original refresh frequency while the original resolution is maintained.

Finally, it should be noted that, relation terms herein such as “the first” and “the second” are only used to distinguish one entity or operation from another entity or operation, without requiring or implying that there is any such actual relation or orders between these entities or operations. Moreover, terms “include”, “comprise” or other modifications thereof are intended to be a non-exclusive inclusion, so that a process, a method, an article or a device, which includes a series of elements, includes not only those elements, but also other elements which are not explicitly listed, or also includes inherent elements of such a process, a method, an article or a device. In the case of no more limitations, elements defined by the statement “include a” does not exclude the existence of additional identical elements in the process, method, article or device including the elements.

The principles and embodiments of the application are described herein by specific examples, and the descriptions of the embodiments above are only used to help understand the method and core idea of the application. In addition, those skilled in the art can made variations to both specific embodiments and application scope according to the idea of the application. In summary, the content of the specification should not be interpreted as limiting the application.

1. A PWM circuit, comprising:
a PWM counter, adapted to count a clock signal;
a reference value setting register, adapted to set a comparison reference value which determines the duty cycle of a PWM signal;
a frequency multiplier, adapted to increase frequency of an clock signal input and to output clock signal with the increased frequency to the PWM counter; and
a comparator, adapted to generate a PWM signal based on a comparison between the comparison reference value and the count value of the PWM counter.

2. The PWM circuit according to claim 1, wherein the frequency multiplier is one of a transistor frequency multiplier, a varactor diode frequency multiplier, a step recovery diode frequency multiplier, a ferrite frequency multiplier, a phase-locked loop frequency multiplier and a synchronous frequency multiplier.

3. The PWM circuit according to claim 1, wherein the PWM circuit further comprises a count value upper-limit setting register, for setting a count value upper-limit which determines the pulse width of the PWM signal in the PWM counter.

4. The PWM circuit according to claim 1, wherein the comparator is adapted to output an “L” level as the PWM signal when the count value of the PWM counter is lower than the comparison reference value, and to output an “H” level as the PWM signal when the count value of the PWM counter is higher than the comparison reference value.

5. The PWM circuit according to claim 1, wherein the comparator is adapted to output an “H” level as the PWM signal when the count value of the PWM counter is lower than the comparison reference value, and to output an “L” level as the PWM signal when the count value of the PWM counter is higher than the comparison reference value.

6. An LED drive circuit, comprising:
a PWM circuit comprising a PWM counter, adapted to count a clock signal; a reference value setting register, adapted to set a comparison reference value which determines the duty cycle of a PWM signal; a frequency multiplier, adapted to increase frequency of an clock signal input and to output clock signal with the increased frequency to the PWM counter; and a comparator, adapted to generate a PWM signal based on a comparison between the comparison reference value and the count value of the PWM counter;
an LED light source; and
a drive module connected between the PWM circuit and the LED light source, for supplying stable current to the LED light source.

7. The LED drive circuit according to claim 6, wherein the frequency multiplier is one of a transistor frequency multiplier, a varactor diode frequency multiplier, a step recovery diode frequency multiplier, a ferrite frequency multiplier, a phase-locked loop frequency multiplier and a synchronous frequency multiplier.

8. The LED drive circuit according to claim 6, wherein the PWM circuit further comprises a count value upper-limit setting register, for setting a count value upper-limit which determines the pulse width of the PWM signal in the PWM counter.

9. The LED drive circuit according to claim 6, wherein the comparator is adapted to output an “L” level as the PWM signal when the count value of the PWM counter is lower than the comparison reference value, and to output an “H” level as the PWM signal when the count value of the PWM counter is higher than the comparison reference value.

10. The LED drive circuit according to claim 6, wherein the comparator is adapted to output an “H” level as the PWM signal when the count value of the PWM counter is lower than the comparison reference value, and to output an “L” level as the PWM signal when the count value of the PWM counter is higher than the comparison reference value.
